(19) United States
(12) Patent Application Publication
(10) Pub. No.: US 2016/0093772 A1
(43) Pub. Date: Mar. 31, 2016

(54) Methods for Reducing Interface Contact Resistivity

(71) Applicant: Intermolecular, Inc., San Jose, CA (US)

(72) Inventors: Khaled Ahmed, Anaheim, CA (US); Frank Greer, Pasadena, CA (US); Andrew Steinbach, San Jose, CA (US)

(21) Appl. No.: 14/501,631

(22) Filed: Sep. 30, 2014

(51) Int. Cl. H01L 33/32; H01L 33/40; H01L 33/00

(52) U.S. Cl. CPC H01L 33/325; H01L 33/0075; H01L 33/40; H01L 33/0095; H01L 2933/0016

(57) ABSTRACT

Provided are methods of forming low resistivity contacts. Also provided are devices having such low resistive contacts. A method may include doping the surface of a structure, such as a gallium nitride layer. Specifically, a dopant containing layer is formed on the surface of the structure using, for example, atomic layer deposition (ALD). The dopant may magnesium. In some embodiments, the dopant containing layer also includes nitrogen. A capping layer may be then formed over the dopant containing layer to prevent dopant desorption. The stack including the structure with the dopant containing layer disposed on its surface is then annealed to transfer dopant from the dopant containing layer into the surface. After annealing, any remaining dopant containing layer is removed. When another component is later formed over the surface, a low resistivity contact is created between this other component and the doped structure.

### BACKGROUND

Group III-V materials and other like materials find many applications in the semiconductor and related industries, such as light emitting diodes. Yet, processing these materials and, in particular, forming electronic contacts with these materials proved to be difficult. For example, high quality surface preservation of select films, e.g. a gallium nitride film, is not straightforward in many applications using stacks of material layers fabricated sequentially. Furthermore, conventional doping techniques are generally too disruptive for these materials. Group III-V materials are often sensitive to process conditions and care must be taken to avoid such conditions at particular periods of the fabrication process, such as doping. Avoiding interaction of a sensitive group III-V film with potential damaging conditions, however, is also not straightforward in many applications.

### SUMMARY

Provided are methods of forming low resistivity contacts. Also provided are devices having such low resistive contacts. A method may include doping the surface of a structure, such as a gallium nitride layer. Specifically, a dopant containing layer is formed on the surface of the structure using, for example, atomic layer deposition (ALD). The dopant may magnesium. In some embodiments, the dopant containing layer also includes nitrogen. A capping layer may be then formed over the dopant containing layer to prevent dopant desorption. The stack including the structure with the dopant containing layer disposed on its surface is then annealed to transfer dopant from the dopant containing layer into the surface. After annealing, any remaining dopant containing layer is removed. When another component is later formed over the surface, a low resistivity contact is created between this other component and the doped structure.

In some embodiments, methods of fabricating a low resistivity interface comprises providing a structure and forming a first layer on a surface of the structure using atomic layer deposition. The structure may be a part of an epitaxial stack of a light emitting diode. The first layer includes a dopant and may be referred to as a dopant containing layer. In some embodiments, the thickness of the first layer is less than 100 nanometers or, more specifically, less than 50 nanometers. The methods may proceed with annealing the structure having the first layer disposed on the surface of the structure. This annealing causes the dopant to diffuse from the first layer into the structure thereby forming a doped portion of the structure. The methods then proceed with removing the first layer from the surface of the structure.

In some embodiments, the methods also involve forming a second layer over the first layer prior to annealing. In this example, the first layer is disposed between the second layer and the structure. Removal of the first layer may also involve removal of the second layer from the surface of the structure. In some embodiments, the second layer is formed at a temperature of less than 400° C. The second layer may be formed using physical vapor deposition. The second layer may have a thickness of greater than 50 nanometers. The second layer may include silicon oxide. In this example, the dopant may be magnesium. The structure may include gallium nitride. When the dopant is magnesium, the first layer may be formed from one of metallic magnesium, magnesium oxide, magnesium fluoride, or magnesium nitride.

In some embodiments, annealing is performed at a temperature of between about 800° C. and 1000° C. The duration of annealing may be between about 30 seconds and 360 seconds. Forming the first layer may be performed at a temperature of less than 600° C. or, more specifically, at a temperature of less than 400° C.

In some embodiments, removing the first layer involves etching the first layer with a solution comprising hydrofluoric acid. As described above, if any other layer is present above the first layer during annealing operation, this other layer may be also removed in the same operation. The etchant composition and/or etching conditions may be adjusted to achieve this multicomponent removal.

The methods may involve cleaning the surface of the structure with hydrogen radicals prior to forming the first layer. Furthermore, the methods may involve cleaning the surface of the structure with hydrogen radicals, after removing the first layer and prior to depositing another material on the doped surface of the structure. In some embodiment, the methods involve depositing an electrode onto the surface of the structure and annealing the structure having the electrode disposed on its surface. The electrode may include a third layer and a fourth layer such that the third layer includes titanium and directly interfaces the surface of the structure, while the fourth layer includes aluminum. The fourth layer is separated from the doped structure by the third layer. The third layer may have a thickness of 10 nanometers and 100 nanometers. Likewise, the fourth layer may have a thickness of 10 nanometers and 100 nanometers.

In some embodiments, the surface resistivity of the structure is less than about 10⁻³ Ohm/square at least at the surface formed by the doped surface. The concentration of the dopant in the structure at the surface may be at least about 10²⁰/cm3.

Also provided is a device including a structure formed from gallium nitride, such that the structure is doped with magnesium. The concentration of magnesium at least in a surface of the structure may be at least about 10²⁰°/cm3. The device also includes an electrode having a third layer and fourth layer. The third layer includes titanium and directly interfaces the surface of the structure. The fourth layer includes aluminum.

These and other embodiments are described further below with reference to the figures.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings.

FIG. 1 illustrates a process flowchart corresponding to a method of fabricating a low resistivity interface, in accordance with some embodiments.

FIG. 2 is a schematic illustration of a partially fabricated device prior to doping, in accordance with some embodiments.

FIG. 3 is a schematic illustration of a partially fabricated device after forming a dopant containing layer and, optionally, capping layer prior to doping a structure disposed under the dopant containing layer, in accordance with some embodiments.

FIG. 4 is a schematic illustration of a partially fabricated device after doping the structure disposed under the dopant containing layer, in accordance with some embodiments.

FIG. 5 is a schematic illustration of a device after removal of the residual dopant containing layer from the surface of the doped structure, in accordance with some embodiments.

FIG. 6 is a schematic illustration of a device after forming an electrode on the surface of the doped structure, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

Gallium nitride is one of the key components in the wide band-gap semiconductor class. It is important for high-power solid-state devices, especially for those intended for microwave frequency range. It is also important for optoelectronics applications, such as LEDs. Gallium nitride based transistors have one of the highest output power density and have the potential to replace gallium arsenide based transistors for a number of high-power applications. Gallium nitride has a number of unique properties not found in many other semiconductors, such as a high breakdown field, high saturation electron velocity, and capacity to support hetero-structure device technology with a high two-dimensional electron gas density and high carrier mobility. Specifically, gallium nitride has a high breakdown field of 3 MV/cm, ten times larger than that of gallium arsenide. Furthermore, gallium nitride allows polarization-induced bulk three-dimensional doping without physically introducing shallow donors. The strong piezoelectric effect and large spontaneous polarization in gallium nitride allows for the incorporation of a large electric field and high sheet charge density without doping. This effect and polarization help to realize a variety of high-performance and high-power microwave devices.

Ion-implantation is commonly used for semiconductor doping, in particular selective area doping of gallium nitride. However, ion-implantation is a highly energetic process and can easily damage the semiconductor crystal lattice of gallium nitride and other like semiconductors. Moreover, implanted dopants generally do not reside in electrically active substitutional sites in the semiconductor lattice of gallium nitride and other like semiconductors. As a result, ion-implantation is generally followed by a high-temperature annealing step for alleviating the implantation-induced lattice damage and for activating the implanted dopants. Gallium nitride structures with n-type dopants, such as silicon, are often annealed to about 1200° C., while gallium nitride structures with p-type dopants, such as magnesium and beryllium, are often annealed at temperatures in excess of 1300° C. The higher temperature requirement for activating p-type implants compared to n-type implants in gallium nitride is primarily due to the much larger formation energy of the substitutional Mg—Ga species compared to the Si—Ga species.

However, when annealed to temperatures above 800° C., gallium nitride can decompose into gallium droplets if nitrogen is allowed to desorb and escape the surface of gallium nitride structure. As such, duration of annealing operations should be kept to minimum. However, reaching high annealing temperatures takes time and is difficult to achieve with equipment that is capable of high heating and/cooling, such as quartz lamps. These problems become even more severe when high dopant concentrations are needed, such as in excesses of 10¹⁸/cm³. Yet, many applications, such as low resistivity interface contact, require dopant concentrations in excesses of 10²⁰/cm³, which cannot be achieved with ion implantation as shown above.

Thermal annealing helps to overcome various limitations of ion implantation recited above. However, gallium nitride has very low diffusion coefficient for many dopants even at very high temperatures. As such, thermal annealing has been generally dismissed as a technique for bulk doping of gallium nitride. It has been found that this low diffusion coefficient can be effectively relied on when surface doping rather than bulk doping is needed. Surface doping is defined as doping of only a portion of a structure, while a remaining portion of the structure remains substantially free from the dopant. The thickness of the doped portion may be less than 25% of the overall thickness of the structure or even less than 10%, such as between about 1-5%. It should be noted that the remaining portion, which is not doped during surface doping, may still include one or more dopants that are introduced by other doping techniques. For example, a p-doped gallium nitride structure having a dopant concentration of less than 10¹⁸/cm³ throughout the entire structure may be subjected to surface doping. After this surface doping, the concentration of dopants at the doped surface may be greater than 10²⁰/cm³ while a large portion of this structure may still have a concentration of dopants of less than 10¹⁸/cm³. In fact, the limiting factor of thermal doping can be exploited to create los resistivity interface contact without significantly impacting bulk properties.

### Processing Examples

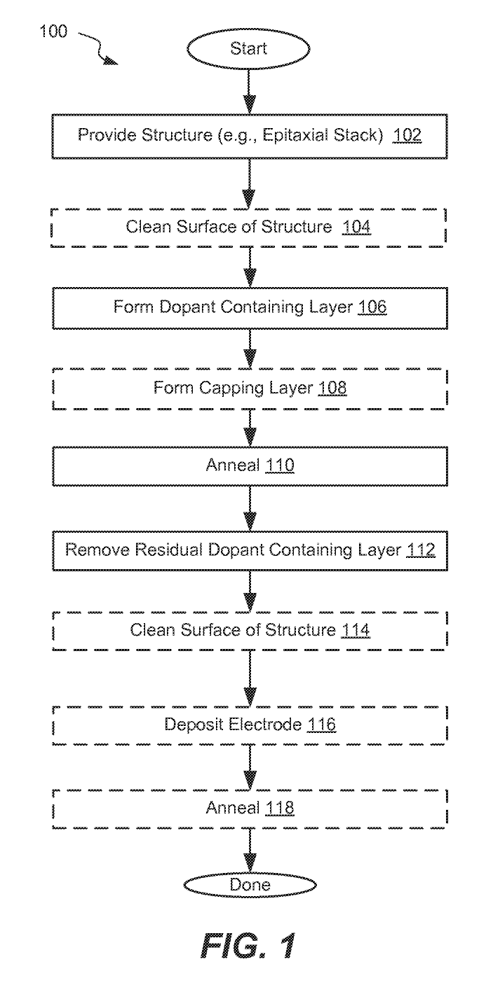

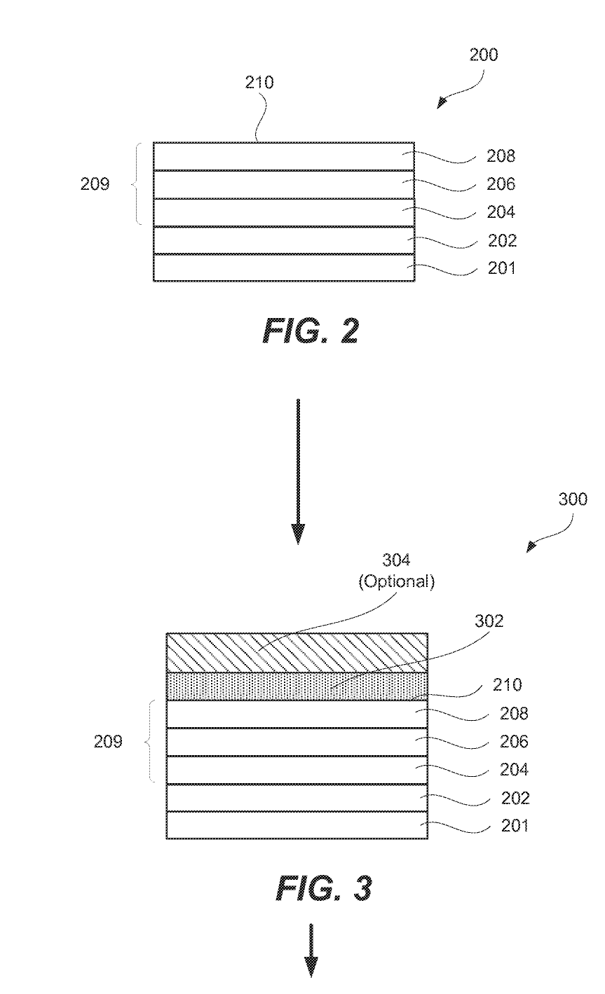

FIG. 1 illustrates a process flowchart corresponding to method 100 of fabricating a low resistivity interface, in accordance with some embodiments. Method 100 may commence with providing a structure during operation 102. This structure is later surface doped using a thermal doping technique. The structure provided during operation 102 may be a part of a device. One examples of a device including a structure that is later doped is presented in FIG. 2. Specifically, FIG. 2 is a schematic illustration of device 200, which may be also referred to as a partially fabricated LED. Device 200 includes epitaxial stack 209 formed on substrate 202. Substrate 202 may be formed from such materials as sapphire, silicon carbide, silicon, zinc oxide, magnesium oxide, aluminum nitride, gallium nitride, or combinations thereof. Substrate 202 may include other components, such as additional LEDs, electrical leads for supplying electrical power to epitaxial stack 209, control circuitry, and such. Back electrode 201 may be formed on the side substrate 202 that is opposite to epitaxial stack 209.

Epitaxial stack 209 may include n-doped semiconductor 204 disposed over substrate 202. In some embodiments, n-doped semiconductor 204 directly interfaces substrate 202. Epitaxial stack 209 may also include active layer 206 disposed on n-doped semiconductor 204 and structure 208, which is doped in a later operation. Structure 208, which may be a layer in some embodiments, may be disposed over active layer 206. Structure 208 may be a p-doped semiconductor. Structure 208 has top surface 210, which later receives an electrode or some other component, such as a TCO layer. Top surface 210 needs to form a low resistivity interface with a component disposed over top surface 210 and directly interfacing structure 208.

In some embodiments, structure 208 includes one of gallium nitride, aluminum gallium nitride, and indium gallium nitride. In some embodiments, structure 208 may be already doped. For example, a concentration of dopants in structure 208 during operation 102 may be less than less than 10¹⁸/cm³. These initially provided dopants may be uniformly distributed within structure 208. The thickness of structure 208 may be between about 100 nanometers and 1000 nanometers. Top surface 210 of structure 208 may have substantially planar as, for example, shown in FIG. 2. Alternatively, top surface 210 may have various features that are not planar. Such surfaces may be referred to as 3D surfaces.

Returning to FIG. 1, method 100 may proceed with cleaning the surface of the provided structure during optional operation 104. For example, the surface of a gallium nitride structure or, more specifically, p-doped gallium nitride structure may be cleaned using hydrogen radicals. These hydrogen radicals may be formed using a remote plasma generator or some other techniques. In general, the plasma used for cleaning may be generated using one or more of nitrogen, argon, hydrogen, or other gas. The radicals and/or ions of these elements may be used to remove substrate surface contaminations and particles. Plasma density, bias, treatment time, and other parameters may be adjusted to effectively clean the substrate surface but not damage the substrate surface (e.g., the bias applied ranges approximately from −5V to −1000V and treatment time ranges approximately from 1 second to 15 minutes).

Method 100 may proceed with forming a dopant containing layer during operation 106. In order to differentiate the dopant containing layer from other layers, such as a capping layer, the dopant containing layer may be referred to as a first layer. Any layer formed above the dopant containing layer may be referred to as a second layer, third layer, and so on. A dopant in the dopant containing layer may be magnesium. For example, the dopant containing layer may include at least one of metallic magnesium, magnesium oxide, magnesium fluoride, or magnesium nitride. FIG. 3 is a schematic illustration of device 300 having dopant containing layer 302. Dopant containing layer 302 is disposed on surface 210 of structure 208. Surface 210 is later doped using dopant containing layer 302. Some dopant may be transferred into structure 208 while forming dopant containing layer 302. However, more dopant is transferred into structure 208 from dopant containing layer 302 in later operations. While device 300 also shows capping layer 304 disposed over dopant containing layer 302, capping layer 304 is optional and device 300 may be formed without capping layer 304 as further described below.

The dopant containing layer may be formed using ALD, or other suitable techniques. The selection of the deposition technique may depend on the shape of the top surface of the structure receiving the dopant containing layer, desired thickness of the dopant containing layer, and other factors. For example, ALD may be more suitable for non-planar surfaces since ALD is capable of forming very thin but conformal layers. Furthermore, ALD may be used to control the amount of dopant deposited on the top surface of the structure, which in turn may control the resulting dopant concentration. Furthermore, ALD may be less damaging than other deposition techniques (such as PVD) to the surface of the semiconductor. Specifically, PVD may cause damage to the surface resulting in Fermi Level Pinning, which may cause an increase in contact resistivity. It should be noted that the methods describes herein are designed to decrease the contact resistivity. As such, PVD may not be applicable for some applications of the described method. Furthermore, PVD may cause various undesirable materials to be incorporated into the deposited structure.

Since very little amounts of dopants are needed for surface doping and forming a low resistivity contact interface, the dopant containing layer may be very thin. In some embodiments, the thickness of the dopant containing layer is less than 100 nanometers or, more specifically, less than 50 nanometers or even less than 20 nanometers. The dopant containing layers that are only 2-10 nanometers thick are suitable for many low resistivity contact applications. As such, ALD may be used for depositing such layers using one or more ALD cycles. The dopant containing layer may be partially or completely consumed during subsequent annealing.

When ALD is used, each ALD cycle involves the following four steps: introducing one or more dopant containing precursors into the deposition chamber to form an adsorbed layer, followed by purging the unadsorbed precursor and any superfluous by-products from the chamber, and then introducing reactive agents that will react with the adsorbed layer to form a portion of or the entire oxide layer, followed by purging the unreacted reactive agents and any superfluous by-products from the chamber. A layer formed during each ALD cycle may be between about 0.25 and 2 Angstroms thick, averaged over the area of the layer. The ALD cycle may be repeated multiple times until the overall base layer reaches it desired thickness. In some embodiments, ALD cycles are repeated using different precursors. The temperature of the substrate during atomic layer deposition may be between about 200° C. to 350° C. The precursor may be either in gaseous phase, liquid phase, or solid phase. If a liquid or solid precursor is used, then it may be transported into the chamber an inert carrier gas, such as helium or nitrogen. Some examples of magnesium containing precursors include bis(cyclopentadienyl)magnesium (Mg(C₅H₅)₂) and bis(pentamethylcyclopentadienyl) magnesium (C₂₀H₃₀Mg). Reactive agents may include oxygen, nitrogen, and/or fluoride.

Regardless of the deposition techniques used during operation 106, the temperature of the structure may not exceed 600° C. or 400° C. for reasons described above. As such, other deposition techniques, such as chemical vapor deposition and its variations, which require high deposition temperature, generally cannot be used.

Method 100 may proceed with forming a capping layer over the dopant containing layer during optional operation 108. If operation 108 is performed and the capping layer is formed, then operation 108 is performed prior to annealing operation 110 further described below. FIG. 3 is a schematic illustration of device 300 having capping layer 304. In this example, dopant containing layer 302 is disposed between capping layer 304 and structure 208.

The capping layer may prevent contamination of the dopant containing layer and underlying structure before and during annealing. Furthermore, the capping layer may prevent desorption of materials from the capping layer during annealing thereby controlling composition of the capping layer. This latter feature is useful when the amount of dopant in the doping containing layer is used to control the dopant concentration in the later doped structure. The capping layer may include silicon oxide. Silicon oxide generally has less residual hydrogen than other types of capping layers. If hydrogen is present in the active layer, then it can migrate into structure 208 and deactivate some of the dopants in this structure. In some embodiments, the capping layer may include silicon oxide in addition to silicon nitride. For example, the capping layer may include a first sub-layer including silicon oxide and a second sub-layer including silicon nitride. The material of the capping layer generally depends on the material of the dopant containing layer. For example, the capping layer may include silicon oxide. In this example, the dopant may be magnesium, while the structure disposed under the dopant containing layer may include gallium nitride.

In some embodiments, the capping layer is formed at a temperature of less than 400° C. The low temperature deposition may be used to avoid damage to the underlying structure. The capping layer may be formed using, for example, physical vapor deposition. The capping layer may have a thickness of greater than 50 nanometers.

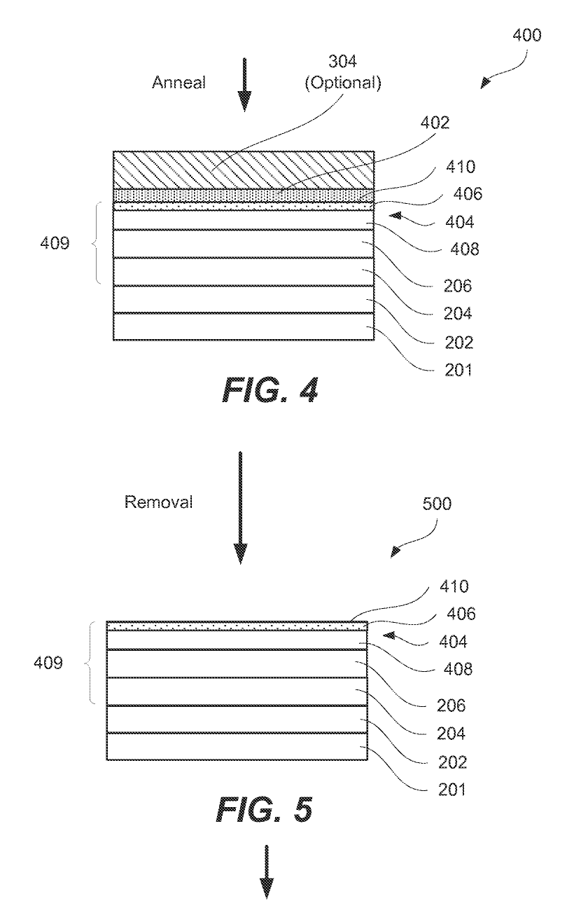

Method 100 may proceed with annealing the structure having the dopant containing layer disposed on its surface during operation 110. During this annealing operation, the dopant diffuses from the dopant containing layer into the structure and forms a doped portion of the structure. FIG. 4 illustrates device 400 having doped structure 404 disposed under residual dopant layer 402, both formed during operation 110. Specifically, doped structure 404 may include doped portion 406 and un-doped portion 408. It should be noted that doped portion 406 includes a dopant transferred from the initial dopant containing layer, which has been converted into residual dopant layer 402 during operation 110, while un-doped portion 408 does not include this dopant. However, as described above, un-doped portion 408 may include other dopants that were present in the structure prior to operation 110, which may be referred to initial dopants in order to differentiate these dopants from the dopant received from the initial dopant containing layer during operation 110. These same initial dopants may be also present in doped portion 406 in addition to the dopant transferred from the initial dopant containing layer.

In some embodiments, annealing operation 110 is performed at a temperature of between about 800° C. and 1000° C. The duration of annealing may be between about 30 seconds and 360 seconds. These conditions may be selected based on the amount of dopant that needs to be transferred, desired thickness of doped portion 406, mobility of dopants, and other factors. In some embodiments, the thickness of doped portion 406 is between about 1 nanometer and 10 nanometers.

In some embodiments, the concentration of the dopant in the structure at the surface or, more generally, in a doped portion of the structure may be at least about 10²⁰/cm3. After operation 110, the dopant concentration in the doped portion may be higher than the average dopant concentration, which is reflective of the surface doping. For purposes of this disclosure, the doped portion formed during operation 110 is defined as a portion that received about 90% of the dopants transferred into the structure from the dopant containing layer. In some embodiments, the surface resistivity of the structure is less than about 10⁻³ Ohm/square at least at the surface or, more generally, within the doped portion.

Method 100 may proceed with removing the residual dopant containing layer during operation 112. In some embodiments, removing the dopant containing layer involves etching the residual dopant containing layer with a solution comprising hydrofluoric acid. When a capping layer is present above the residual dopant containing layer, the capping layer and residual dopant containing layer may be removed in the same operation. The etchant composition and/or etching conditions may be adjusted to achieve this multicomponent removal. FIG. 5 illustrates device 500 with surface 410 of doped structure 404 exposed after removing at least the residual dopant containing layer. As described above, surface 410 is formed by doped portion 406 of doped structure 404.

Method 100 may involve cleaning the surface of the doped structure after removing the dopant containing layer during optional operation 114. Operation 114 may be similar to operation 104 described above. For example, the surface of the doped structure may be cleaned using hydrogen radicals.

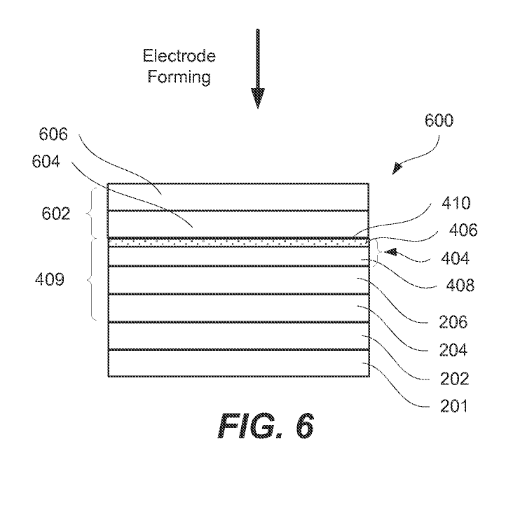

In some embodiments, method 100 involves depositing an electrode onto the surface of the structure during optional operation 116. The electrode may include a third layer and a fourth layer such that the third layer includes titanium and directly interfaces the surface of the structure, while the fourth layer includes aluminum. The fourth layer is separated from the doped structure by the third layer. The third layer may have a thickness of 10 nanometers and 100 nanometers. Likewise, the fourth layer may have a thickness of 10 nanometers and 100 nanometers. FIG. 6 is a schematic representation of device 600 with electrode 602 disposed on doped structure 404. Specifically, electrode 602 includes top layer 606 and bottom layer 604. Top layer 606 may include aluminum, and bottom layer 604 may include titanium. In some embodiments, bottom layer 604 directly interfaces doped portion 406 of doped structure 404 formed during operation 110 described above. As such, the interface between bottom layer 604 and interfaces doped portion 406, which is defined by surface 410, may be a low resistivity contact interface.

Method 100 may involve annealing the device having an electrode during optional operation 118. If the electrode has two or more layers having different compositions, the composition becomes more uniform within the electrode by intermixing materials within these two or more layers.

### Conclusion

Although the foregoing examples have been described in some detail for purposes of clarity of understanding, the invention is not limited to the details provided. There are many alternative ways of implementing the invention. The disclosed examples are illustrative and not restrictive.

1. A method of fabricating a low resistivity interface, the method comprising:
providing a structure comprising gallium nitride;
forming a first layer on a surface of the structure using atomic layer deposition,
wherein the first layer comprises a dopant, and
wherein the dopant is magnesium;
annealing the structure having the first layer disposed on the surface of the structure,
wherein annealing causes the dopant to diffuse from the first layer into the structure thereby forming a doped portion of the structure; and
removing the first layer from the surface of the structure.

2. The method of claim 1, further comprising, prior to annealing, forming a second layer over the first layer such that the first layer is disposed between the second layer and the structure, wherein removing the first layer comprises removing the second layer from the surface of the structure.

3. The method of claim 2, wherein the second layer is formed at a temperature of less than 400° C.

4. The method of claim 3, wherein the second layer is formed using physical vapor deposition.

5. The method of claim 2, wherein the second layer has a thickness of greater than 50 nanometers.

6. The method of claim 2, wherein the second layer comprises silicon oxide.

7. The method of claim 6, wherein the first layer comprises one of metallic magnesium, magnesium oxide, magnesium fluoride, or magnesium nitride.

8. The method of claim 1, wherein annealing is performed at a temperature of between about 800° C. and 1000° C.

9. The method of claim 1, wherein removing the first layer comprises etching the first layer with a solution comprising hydrofluoric acid.

10. The method of claim 1, wherein a thickness of the first layer is less than 100 nanometers.

11. The method of claim 1, wherein a thickness of the first layer is less than 50 nanometers.

12. The method of claim 1, further comprising, prior to forming the first layer, cleaning the surface of the structure with hydrogen radicals.

13. The method of claim 1, further comprising, after removing the first layer, cleaning the surface of the structure with hydrogen radicals.

14. The method of claim 1, further comprising depositing an electrode onto the surface of the structure and annealing the structure having the electrode disposed on its surface.

15. The method of claim 14, wherein the electrode comprises a third layer and a fourth layer, wherein the third layer comprises titanium and directly interfaces the surface of the structure, and wherein the fourth layer comprises aluminum.

16. The method of claim 15, wherein the third layer has a thickness of 10 nanometers and 100 nanometers, and wherein the fourth layer has a thickness of 10 nanometers and 100 nanometers.

17. The method of claim 1, wherein the surface resistivity of the structure is less than about 10⁻³ Ohm-square at least at the surface.

18. The method of claim 1, wherein a concentration of the dopant in the structure at the surface is at least about 10²⁰/cm³.

19. The method of claim 1, wherein the structure is a part of an epitaxial stack of a light emitting diode.

20. A device comprising:
a structure comprising gallium nitride,
wherein the structure is doped with magnesium,
wherein a concentration of magnesium at least in a surface of the structure is at least about 10²⁰/cm³; and
an electrode comprises a third layer and a fourth layer,
wherein the third layer comprises titanium and directly interfaces the surface of the structure, and
wherein the fourth layer comprises aluminum.
